(19) United States
(12) Patent Application Publication
(10) Pub. No.: US 2009/0246373 A1
(43) Pub. Date: Oct. 1, 2009

(54) METHOD OF FORMING METALLIC FILM AND PROGRAM-STORING RECORDING MEDIUM

(75) Inventors: Mitsuhiro Tachibana, Yamanashi (JP); Masahito Sugiura, Yamanashi (JP); Takashi Nishimori, Yamanashi (JP); Kohichi Satoh, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Tokyo Electron Limited, Minato-ku, Tokyo (JP)

(21) Appl. No.: 12/063,517

(22) PCT Filed: Jul. 6, 2006
(86) PCT No.: PCT/JP2006/313460

§ 371 Date: Oct. 7, 2008

(30) Foreign Application Priority Data
Aug. 11, 2005 (JP) 2005-233819

(51) Int. Cl. C23C 16/06; G05B 13/02

(52) U.S. Cl. 427/255.23; 700/266

(57) ABSTRACT

A metal film with a lowered resistance by controlling a crystal structure. A tungsten film is formed through a first tungsten film formation in which a first tungsten film with amorphous content is formed by alternately executing multiple times a supplying a metal base material gas such as WF₆ gas and supplying a hydrogen compound gas such as SiH₄ gas, with a purge executed between the two gas supply by supplying an inert gas such as Ar gas or N₂ gas and a second tungsten film formation in which a second tungsten film is formed by simultaneously supplying the WF₆ gas and a reducing gas such as H₂ gas onto the first tungsten film. The amorphous content in the first tungsten film is controlled by adjusting the length of time over which the purge is executed following the SiH₄ gas supply.

### TECHNICAL FIELD

The present invention relates to a metal film forming method that may be adopted when forming a metal film on the surface of a processing target piece and a recording medium having a program recorded therein.

### BACKGROUND ART

Semiconductor device manufacturing processes normally include a step in which a metal film is formed at the surface of the processing target material such as a semiconductor wafer (hereafter may be simply referred to as a “wafer”). A metal film must be formed when, for instance, forming a wiring pattern at a wafer surface or filling recesses (via holes) between wirings or recesses (contact holes) for substrate contact. The metal film may be a thin film formed by depositing metal or a metal compound such as W (tungsten), WSi (tungsten silicide), WN (tungsten nitride), Ti (titanium), TiN (titanium nitride) or TiSi (titanium silicide).

The resistance of the metal film used for wiring purposes or the like should be as low as possible. The tungsten film among the metal films listed above, which has a particularly low specific resistance is deemed desirable from this viewpoint and, accordingly, it is widely used when filling recesses between wirings and substrate contact recesses.

The tungsten film is usually formed through deposition by using WF₆ (tungsten hexafluoride) gas as a metal base material gas and reducing the metal base material gas with a reducing gas such as hydrogen, silane or difluorosilane. In addition, before forming the tungsten film, a barrier layer to act as a base film, constituted with a TiN film deposited on the wafer surface or a laminated film (TiN/Ti film) constituted with a Ti film and a TiN film deposited on the Ti film, is formed to assure better adhesion of the tungsten film and deter a reaction with the lower wiring metal layer or the substrate. The tungsten film is then deposited over the barrier layer.

The tungsten film is usually formed through two phases, i.e., a first step and a second step. In the first step, the tungsten nucleus is formed on the barrier layer (nucleation step). In more specific terms, WF6 gas is supplied to the space above the wafer and a thin tungsten film is formed by reducing the WF₆ gas primarily with SiH₄ gas in the first step. In the second step, a tungsten film is formed over the tungsten nucleation layer having been formed through the first step. The second step may be executed by, for instance, supplying WF₆ gas to the space above the tungsten nucleation layer, supplying a reducing gas constituted of H₂ gas with a lower level of reducing strength than the SiH₄ gas, depositing a thick tungsten film through CVD (chemical vapor deposition) and thus filling the recesses with tungsten. Subsequently, the entire wafer surface is etched back and contact plugs are formed by selectively leaving the tungsten in the recess unetched.

However, depending upon the type of film used as the base film or the surface conditions, a period of incubation (film formation delay) occurs during the nucleation step and, in such a case, the tungsten nucleus cannot be formed uniformly. The quality of a tungsten film deposited over an ununiformly nucleus is bound to be poor, and the resistance of such a tungsten film is bound to be high. Accordingly, an ALD (atomic layer deposition) method whereby the thin film is formed in the first step by alternately supplying the WF₆ gas and a hydrogen compound gas such as SiH₄ (monosilane) gas or B₂H₆ (diborane) gas so as to inhibit the occurrence of an incubation period (see, for instance, patent reference literatures 1 and 2). The ALD method allows a thin film to be formed uniformly over minute contact holes, which, in turn, allows a good quality tungsten film to be deposited over a significant thickness above the thin film used as the nucleus and, consequently allows the contact holes to be filled completely.

(Patent reference literature 1) Japanese Laid Open Patent Publication No. 2002-038271
(Patent reference literature 2) Japanese Laid Open Patent Publication No. 2003-193233

### DISCLOSURE OF THE INVENTION

### Problems to be Solved by the Invention

As future generations of semiconductor devices with even smaller semiconductor device elements are expected to operate at increasingly higher speed, the contact (via) resistance needs to be lowered by assuring an even lower resistance at the metal film such as a tungsten film. However, there is a limit to the extent to which the resistance can be lowered as long as the tungsten film or the like is formed through the film forming methods in the related art described above. In other words, a metal film forming method that will enable formation of a metal film with a lower resistance than those in the related art must be conceptualized from a new perspective, different from those assumed in the related art.

An object of the present invention, having been completed by addressing the issues discussed above, is to provide a metal film forming method through which a metal film with a lower resistance compared to the related art can be formed and a recording medium having a program recorded therein, by assuming a new perspective different from those of the related art, i.e., by focusing on the aspect of the metal film crystal structure.

### Means for Solving the Problems

The object described above is achieved in an aspect of the present invention by providing a metal film forming method comprising a first metal film formation step in which a partially amorphous first metal film is formed by alternatively supplying multiple times a metal base material gas and a hydrogen compound gas and a second metal film formation step in which a second metal film is formed on top of the first metal film by simultaneously supplying the metal base material gas and a reducing gas. The crystalline structure of the second metal film at least may be a body-centered cubic structure.

According to the present invention described above, conceived based upon the principle that the second metal film formed over a partially amorphous first metal film tends to readily assume an orientation with the highest atomic density and a stable atomic arrangement, a metal film with lower resistance can be formed. By forming the first metal film by ensuring that it is at least partially amorphous, the crystalline structure of the second metal film to be formed over the first metal film can be altered to assure a lower resistance. Then, by increasing the ratio of the film thickness of the second metal film to the film thickness of the first metal film, the resistance of the overall metal film can be reduced. It is to be noted that a second metal film with a body-centered cubic crystalline structure tends to readily assume the (110) plane orientation that allows the atoms to arrange themselves with a high level of stability and the highest atomic density.

In addition, it is desirable that the first metal film be formed in the first metal film formation step by alternately executing multiple times a step in which the metal base material gas is supplied and a step in which the hydrogen compound gas is supplied with a purge step executed in between by supplying an inert gas. Through the purge step executed between the metal base material gas supply step and the hydrogen compound gas supply step, the residual gas remaining on the wafer surface and inside the processing container can be eliminated. Since the residual hydrogen compound gas can be eliminated through the purge step executed after the hydrogen compound gas supply step, the process of crystallization of the first metal film can be inhibited, which enables formation of a first metal film that is at least partially amorphous.

During the purge step executed in the method described above, the ratio of the amorphous content in the first metal film may be altered by adjusting the length of time over which the purge step is executed after the hydrogen compound gas supply step. Since the residual hydrogen compound gas can be presumably eliminated more thoroughly if the purge step is executed over a greater length of time following the hydrogen compound gas supply step, for instance, the ratio of the amorphous content in the first metal film can be adjusted by thus inhibiting the crystallization of the first metal film to a greater extent.

In addition, at least the purge step executed after the hydrogen compound gas supply step in the method described above may further include a step in which the inert gas supply is stopped so as to alter the ratio of the amorphous content in the first metal film. By stopping the supply of the inert gas during, for instance, an intermediate phase in the purge step, the processing container internal pressure is lowered rapidly. Such a change in the pressure enhances the effectiveness of the residual gas elimination from the wafer surface and the processing container and, as a result, the ratio of the amorphous content in the first metal film can be adjusted by inhibiting the crystallization of the first metal film.

It is to be noted that the metal base material gas may be, for instance, a halogen compound gas such as WF₆ gas. The hydrogen compound gas may be SiH₄ gas, B₂H₆ gas or a mixed gas containing both the SiH₄ gas and the B₂H₆ gas.

The ratio of the amorphous content in the first metal film may be adjusted by diluting the hydrogen compound gas with a diluting gas having a reducing property (e.g., H₂ gas) in the method described above. The hydrogen compound gas used in such a case may be, for instance, B₂H₆ gas or PH₃ gas. Furthermore, it is desirable that the hydrogen compound gas be diluted with the H₂ gas to 5% or lower. The B₂H₆ gas, PH₃ gas or the like has a higher level of reducing strength than SiH₄ gas and thus, by using B₂H₆ gas or PH₃ gas diluted with, for instance, H₂ gas, less excess gas is allowed to remain on the wafer surface and since the residual gas in the processing container can be completely eliminated, re-adhesion of the gas onto the wafer surface is prevented even if the subsequent purge step is executed over a smaller length of time. In other words, even if the purge step is executed over a shorter period of time following the B₂H₆ gas supply step, a first tungsten film with amorphous content can be formed with a high level of reliability.

The subject described above is also achieved in another aspect of the present invention by providing a computer-readable recording medium having recorded therein a program that enables a computer to execute a first metal film formation step in which a first metal film with amorphous content by alternately executing multiple times a metal base material gas supply step and a hydrogen compound gas supply step with a purge step executed by supplying an inert gas between the metal base material gas supply step and a hydrogen compound gas supply step, and a second metal film formation step in which a second metal film is formed on top of the first metal film by simultaneously supplying the metal base material gas and a reducing gas.

As the first metal film formation step and the second metal film formation step are executed based upon the program read out from the recording medium, a first metal film with amorphous content is formed and a second metal film formed on top of the first metal film with the amorphous content is likely to assume an orientation (e.g., the 110 plane orientation in a body-centered cubic structure) with the highest atomic density and a stable atomic arrangement. By increasing the ratio of the film thickness of the second metal film to the film thickness of the first metal film, a metal film with significantly lower resistance compared to that of a metal film with the first metal film thereof assuming crystalline characteristics can be formed.

### EFFECT OF THE INVENTION

As described above, the present invention provides a metal film forming method through which a metal film with lower resistance compared to metal films formed through methods in the related art can be formed and a recording medium having a program recorded therein.

### BRIEF DESCRIPTION OF THE DRAWINGS

FIG. 1 is a sectional view presenting a structural example for the film forming apparatus in an embodiment of the present invention;

FIG. 2A is an illustration of a specific example of a plane orientation (110) that may be assumed in a body-centered cubic structure;

FIG. 2B is an illustration of a specific example of a plane orientation (100) that may be assumed in a body-centered cubic structure;

FIG. 2C is an illustration of a specific example of a plane orientation (111) that may be assumed in a body-centered cubic structure;

FIG. 2D is an illustration of a specific example of a plane orientation (200) that may be assumed in a body-centered cubic structure;

FIG. 3 presents a gas supply mode that may be adopted to supply various gases in the embodiment;

FIG. 4A is a schematic illustration of a process of forming a tungsten film at a wafer surface;

FIG. 4B is a schematic illustration of a process of forming a tungsten film at the wafer surface;

FIG. 4C is a schematic illustration of a process of forming a tungsten film at the wafer surface;

FIG. 4D is a schematic illustration of a process of forming a tungsten film at the wafer surface;

FIG. 5 presents a gas supply mode that may be adopted to supply various gases when B₂H₆ gas is used as the hydrogen compound gas;

FIG. 6 presents an electron beam diffraction image of a first tungsten film with crystalline characteristics observed through an electron beam diffraction method;

FIG. 7 presents an electron beam diffraction image of a first tungsten film assuming a structure containing both crystalline characteristics and amorphous characteristics observed through an electron beam diffraction method;

FIG. 8 presents an electron beam diffraction image of a first tungsten film with amorphous characteristics observed through an electron beam diffraction method;

FIG. 9 presents the results obtained by examining the crystalline structure of the overall tungsten film;

FIG. 10 presents the results obtained by examining the specific resistance of the overall tungsten film; and

FIG. 11 presents a gas supply mode that may be adopted to supply various gases when an inert gas supply stop step is executed during the purge step.

### EXPLANATION OF REFERENCE NUMERALS

100 film forming apparatus
114 processing container
116 showerhead unit
118 seal member
120 gas injection hole
122 reflector
124 holding member
126 stage
128 lifter pin
130 ring member
132 raising rod
134 lifter pin holes
136 bellows
138 actuator
140 discharge port
142 pressure control valve
146 evacuation system
148 gate valve
150 seal member
151 transmitting window
152 heating lamp chamber
154 heating lamp
156 rotary base
158 rotary motor
160 control unit
162 storage medium
210 contact hole
220 barrier layer
230 first tungsten film (first metal film) second tungsten film (second metal film)
250 contact plug
M wafer

### MODE FOR CARRYING OUT THE INVENTION

The following is a detailed explanation of the best mode for carrying out the present invention, given in reference to the attached drawings. It is to be noted that in the description and the drawings, the same reference numerals are assigned to components having substantially identical functions and structural features to preclude the necessity for a repeated explanation thereof.

### (Structural Example for the Film Forming Apparatus)

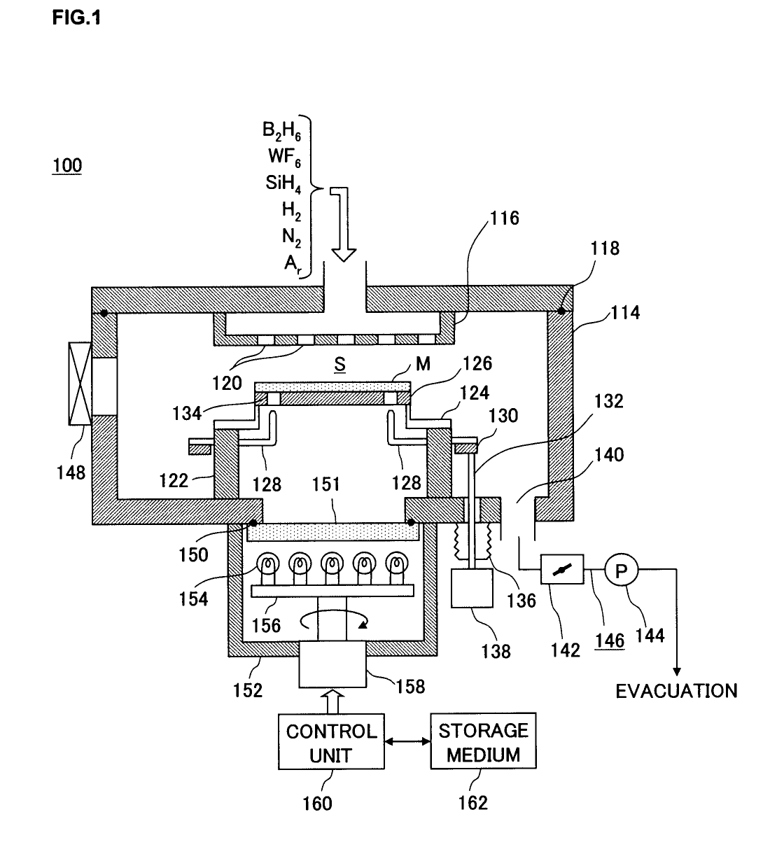

The film forming apparatus achieved in an embodiment of the present invention is first explained in reference to a drawing. FIG. 1 shows the structure of a film forming apparatus achieved in the embodiment of the present invention in a sectional view. The film forming apparatus 100 includes an aluminum processing container 114 having, for instance, a substantially cylindrical section. A showerhead unit 116 functioning as a gas supply means for delivering, either simultaneously or selectively, various types of film formation gases, an inert gas and the like, to be used as processing gases, into the processing container 114 at controlled flow rates, is installed at the ceiling inside the processing container 114 via a seal member 118 such as an O-ring. The film formation gases are thus injected toward a processing space S through numerous gas injection holes 120 formed at the bottom surface of the showerhead unit.

The showerhead unit 116 may assume a structure that includes a single diffuser plate with a plurality of diffusion holes formed therein or a plurality of such diffuser plates so as to promote diffusion of gases delivered therein or a structure with the internal space divided into a plurality of partitioned chambers so as to separately inject gases delivered into the individual chambers toward the processing space S. The showerhead unit should adopt the optimal structure in correspondence to the types of gases used in the film forming apparatus. While B₂H₆ (diborane) gas, WF₆ gas, SiH₄ (monosilane) gas, H₂ gas, N₂ gas, Ar gas and the like may be used as processing gases, the flow rate of each gas is independently controlled via a flow rate controller (not shown) such as a mass flow controller and the start/stop of the gas supply can be individually controlled as well. It is to be noted that the B₂H₆ gas may be diluted to 5% content by using, for instance, H₂ as a diluting gas, as described later.

A stage 126 on which the processing target material, i.e., a wafer M, is placed is installed via three L-shaped holding members 124 (FIG. 1 shows only two of them) on top of a cylindrical reflector 122 extending upright from the bottom of the processing container.

Under the stage 126, a plurality of L-shaped lifter pins 128, e.g., three lifter pins (only two are shown in the figure), are disposed so as to range upward, with the bases of the lifter pins 128 all connected to a ring member 130 through longitudinally elongated insertion holes (not shown) formed at the reflector 122. As the ring member 130 is made to move up/down via a lifting rod 132 passing through the bottom of the processing container, the lifter pins 128 are pushed through lifter pin holes 134 passing through the stage 126 and, as a result, the wafer M becomes lifted up.

An expandable bellows 136 is mounted at the container bottom over the area through which the lifting rod 132 is inserted so as to sustain the inner space of the processing container 114 in an airtight state, with the lower end of the lifting rod 132 connected to an actuator 138.

In addition, a discharge port 40 is formed at the processing container 114 at a bottom edge and an evacuation system 146, which includes a pressure control valve 142 and a vacuum pump 144 disposed in sequence, is connected to the discharge port 140 so as to evacuate the processing container 114 until a specific degree of vacuum is achieved. In addition, the wafer W is carried into/out of the processing container 114 through a gate valve 148 mounted at the side wall of the processing container 114, which is opened/closed for wafer transfer.

At the container bottom directly under the stage 126, a transmitting window 151 constituted of a heat ray transmitting material such as quartz is installed via a seal member 150 such as an O-ring, so as to sustain airtightness. A box-shaped heating lamp chamber 152, is formed under the transmitting window so as to enclose the transmitting window 151. A plurality of heating lamps 154, constituting a heating means, are mounted at a rotary base 156 that is also used as a reflecting mirror inside the heating lamp chamber 152. The rotary base 156 is caused to rotate via a rotating shaft by a rotation motor 158 installed at the bottom of the heating lamp chamber 152. Accordingly, heat rays radiated from the heating lamps 154 are transmitted through the transmitting window 151 and radiate the lower surface of the thin stage 126, thereby heating the stage 126 and also indirectly heating the wafer M placed on the stage 126. Instead of the heating lamps described above, a heating means constituted with an ohmic resistance heater installed at the stage 126 may be used to heat the wafer M.

A control unit 160 constituted with, for instance, a microcomputer is provided to control the overall operations of the film forming apparatus 100. The control unit 160 executes a sequence of control operations that must be executed during film formation processing, e.g., supply start/stop control for the various types of gases, flow rate control for the various gases, wafer temperature control and pressure control. In addition, a storage medium 62 constituted with, for instance, a floppy disk or a flash memory, having stored therein a program in conformance to which the overall apparatus operations are controlled, is loaded in the control unit 160.

### (Example of Film Forming Apparatus Operations)

Next, an example of operations executed in the film forming apparatus 100 structured as described above is explained. The individual operational procedures are executed in the film forming apparatus 100 based upon programs stored in the storage medium 162, as explained earlier.

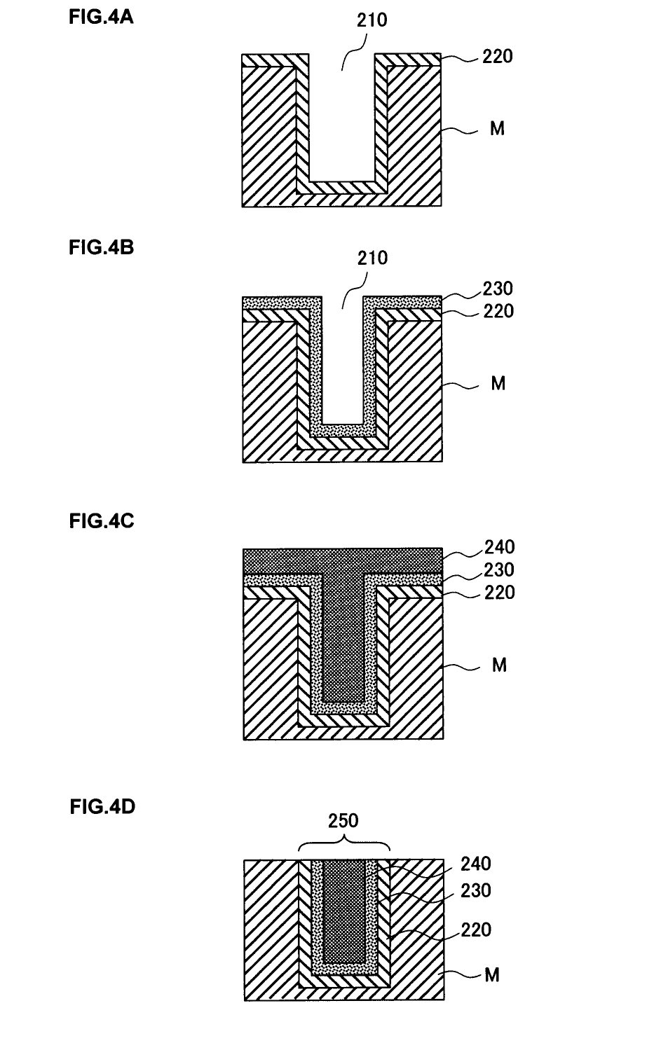

First, the gate valve 148 at the side wall of the processing container 114 is opened to allow a transfer arm (not shown) to carry a wafer M into the processing container 114 and as the lifter pins 128 are lifted up, the wafer M becomes supported by the lifter pins 128. The lifter pins 128 are then made to descend by lowering the lifting rod 132 and the wafer M is thus placed onto the stage 126. A barrier layer 220, which may be constituted with a TiN/Ti film to be used as the base film, will have already been formed over the surface of the wafer M, including the inner surfaces of contact holes 210 such as that shown in FIG. 4A, through a preliminary process. Instead of using a barrier layer 220 assuming a laminated structure, e.g., the TiN/Ti film mentioned above, a barrier layer 220 assuming a single-layer structure constituted with, for instance, a TiN film may be used.

Next, a specific type of film formation gases such as a metal base material gas and a reducing gas, an inert gas and the like to be used as the processing gases are supplied from processing gas sources (not shown) at specific flow rates to the showerhead unit 116 functioning as the gas supply means by adopting the gas supply mode to be detailed later. The processing gases are then supplied into the processing container 114 with substantial uniformity through the gas injection holes 120 at the lower surface of the showerhead unit. At the same time, the internal atmosphere is sucked out through the discharge port 140, thereby evacuating the processing container 114 to achieve a desired pressure and also, the heating lamps 154 constituting the heating means, located under the stage 126, are rotationally driven so as to radiate thermal energy.

The radiated heat rays are transmitted through the transmitting window 151 and then irradiate the rear surface of the stage 126, thereby heating the stage. Since the thickness of the stage 126 is extremely small at, for instance, approximately 1 mm, as mentioned earlier, the stage becomes heated quickly and thus, the wafer M placed thereupon can also be quickly heated to achieve a specific temperature. The film formation gas delivered to the wafer induces a specific chemical reaction allowing a thin metal film such as a thin tungsten film to be deposited over the entire wafer surface.

### (Principal of the Metal Film Forming Method According to the Present Invention)

Metal films with low resistance levels, e.g., the tungsten film described above, are widely used to fill recesses between wirings and recesses for substrate contact, formed on wafers. As semiconductor devices are expected to be further miniaturized and to operate at even higher speeds in the future, the resistance of metal films such as tungsten films also must be further decreased so as to assure lower contact (via) resistance.

The inventor of the present invention et al. have conducted extensive tests in search of a method for forming a metal film with lower resistance, and through these tests, the inventor of the present invention et al. discovered that a metal film such as a tungsten film with an even lower resistance can be formed by controlling its crystal structure. This point is explained in further detail in reference to drawings.

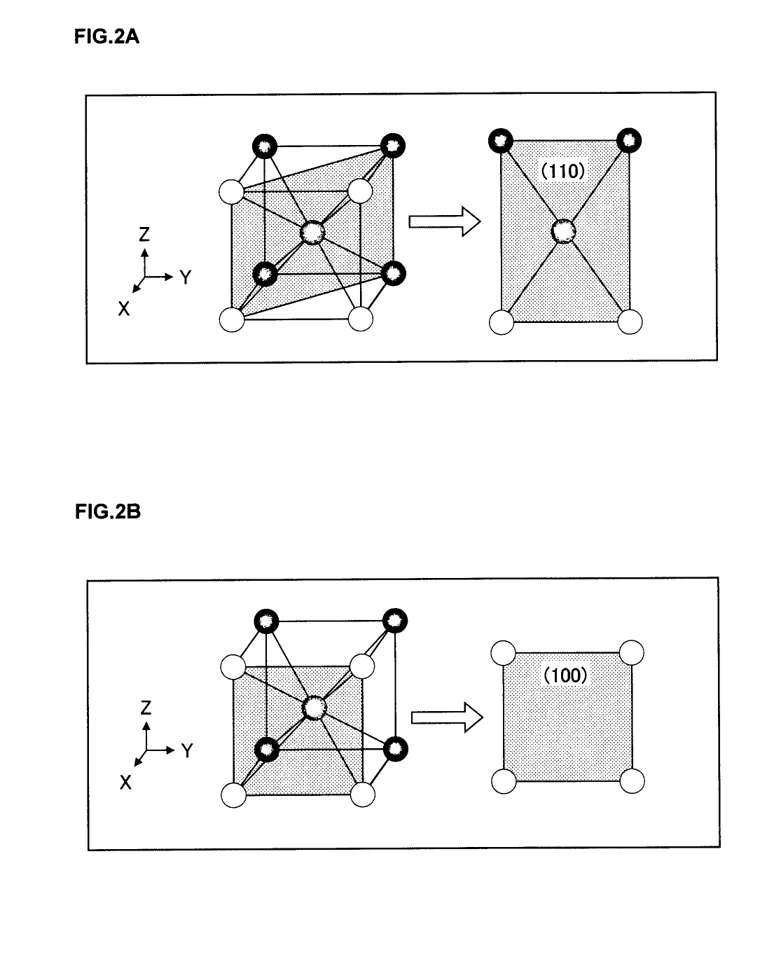

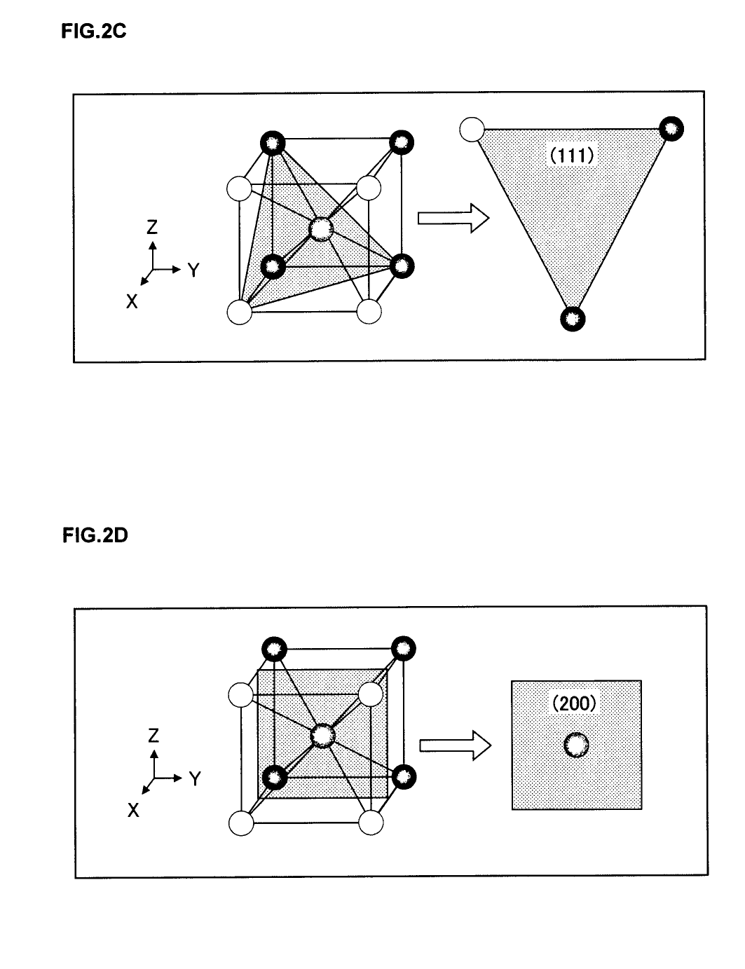

A metal film assuming a body-centered cubic (BCC) structure, such as a tungsten film, is now described. FIGS. 2A through 2D each present a specific example of a primary crystal lattice plane orientation (plane orientation) that may be assumed in a body-centered cubic structure. The size of the atoms is reduced in the illustrations presented in FIGS. 2A through 2D so as to show the lattice planes clearly. In addition, FIGS. 2A through 2D do not include illustrations of atoms that would be visible under the lattice planes.

The plane orientations assumed in the body-centered cubic structures in FIG. 2, each expressed as a plane index (or a mirror index), are (110), (100), (111) and (200) respectively for the plane orientations in FIGS. 2A through 2D. As FIGS. 2A through 2D indicate, the atomic density becomes higher in the order of; (200), (111), (100) and (110).

The (110) plane orientation assumed in a body-centered cubic structure achieves the highest atomic density and thus, a metal film with a more dominant (110) plane orientation is assumed to have a lower resistance. In other words, it is desirable that the crystalline structure of the metal film assume a more dominant (110) plane orientation so as to assure lower resistance (specific resistance) at the metal film.

However, the crystalline structure of the base film affects a metal film formed through a film forming method in the related art. This means that the metal film formed through a method in the related art does not always assume a dominant (110) plane orientation. In other words, if a metal film with a dominant (110) plane orientation can be formed by minimizing the extent to which the formation of the metal film is affected by the crystalline structure of the base film, the metal film will assure a lower resistance level compared to those in the related art.

Accordingly, the inventor of the present invention et al. conducted extensive tests and examinations, through which it was learned that the (110) plane orientation at a second metal film formed over a first metal film becomes more dominant in a metal film with a body-centered cubic structure when the ratio of the amorphous content in the first metal film is higher. Furthermore, it has been confirmed that as long as the film forming method is simply modified so as to raise the ratio of the amorphous content in the first metal film, even a second metal film formed through a film forming method in the related art will assure a dominant (110) plane orientation.

The first metal film with a high amorphous content ratio is assumed to allow a second metal film to form without being affected by the crystalline structure (e.g., the lattice plane interval) of the first metal film and such a second metal film is considered to readily assume a crystalline structure with a dominant (110) plane orientation with the highest atomic density and a high level of atomic arrangement stability.

If the first metal film has a crystalline structure that is completely crystalline, the second metal film will grow under significant influence of the crystalline structure (e.g., the lattice plane interval) of the first metal film. Thus, if the first metal film assumes, for instance, a dominant (200) plane orientation with a lower atomic density than the (110) plane orientation, as in the case of a first metal film formed through a film forming method in the related art, the second metal film formed over the first metal film, too, is likely to assume a crystalline structure with a dominant (200) plane orientation and, as a result, the crystalline structure of the overall metal film, too, will have a dominant (200) plane orientation.

For instance, when a first tungsten film to function as a nucleation layer is formed on top of a base film such as a TiN film to act as a barrier layer, the first tungsten film is affected by the face-centered cubic (FCC) crystalline structure of the TiN film and, as a result, a first tungsten film with a dominant (200) plane orientation tends to be formed readily. This, in turn, results in the formation of a second tungsten film assuming a crystalline structure with a dominant (200) plane orientation over the first tungsten film and consequently, the crystalline structure of the overall tungsten film will have a dominant (200) plane orientation with a lower atomic density than the (110) plane orientation.

Accordingly, a first metal film with some amorphous content is formed by controlling its crystal growth in the present invention. Through these measures, the extent to which the tungsten film formation is affected by the crystalline structure of the base film such as the barrier layer is minimized and a second metal film with a crystalline structure (e.g., the crystalline structure with a dominant (110) plane orientation) with lower resistance (specific resistance) can be formed on top of the first metal film.

Furthermore, since a metal film such as a tungsten film is formed by setting the film thickness of the second metal film greater than the film thickness of the first metal film, the characteristics of the entire metal film such as the specific resistance are determined in correspondence to the characteristics of the second metal film to a greater extent. According to the present invention, the resistance of the second metal film with a greater film thickness ratio is reduced and thus, the resistance of the overall metal film can also be reduced.

In addition, according to the present invention, the resistance of the first metal film is not lowered and thus, the resistance of the overall metal film is reduced by forming the first metal film with a small film thickness relative to the overall film thickness of the metal film. For instance, the first metal film may be formed over a small enough thickness to be regarded as insignificant relative to the overall film thickness of the metal film so as to greatly reduce the resistance of the entire metal film.

The resistance of the overall metal film also tends to decrease when the amorphous content in the first metal film is higher. Accordingly, a first metal film should be formed so as to achieve a high ratio of amorphous content, ideally, to the point where the first metal film becomes completely amorphous. According to the present invention, the crystalline structure of the second metal film formed over the first metal film can be controlled by adjusting the amorphous content in the first metal film and consequently, a metal film with an even lower resistance can be formed.

### (Specific Example of the Metal Film Forming Method)

The metal film forming method achieved in the embodiment by adopting the principal of the present invention described above is explained below. The following is an explanation of a process through which a metal film, e.g., a tungsten film, is formed over a barrier layer formed at contact holes or via holes. In the embodiment, the tungsten film is formed through 2-stage film formation steps which include a first tungsten film formation step executed as the first metal film formation step and a second tungsten film formation step executed as the second metal film formation step. Namely, after forming the first tungsten film with amorphous content through the first tungsten film formation step, a second tungsten film is formed over the first tungsten film through a second tungsten film formation step. Such a second tungsten film will assume a crystalline structure with a lower resistance, i.e., a crystalline structure with the highest atomic density and a high level of stability (e.g., a crystalline structure with a dominant (110) plane orientation).

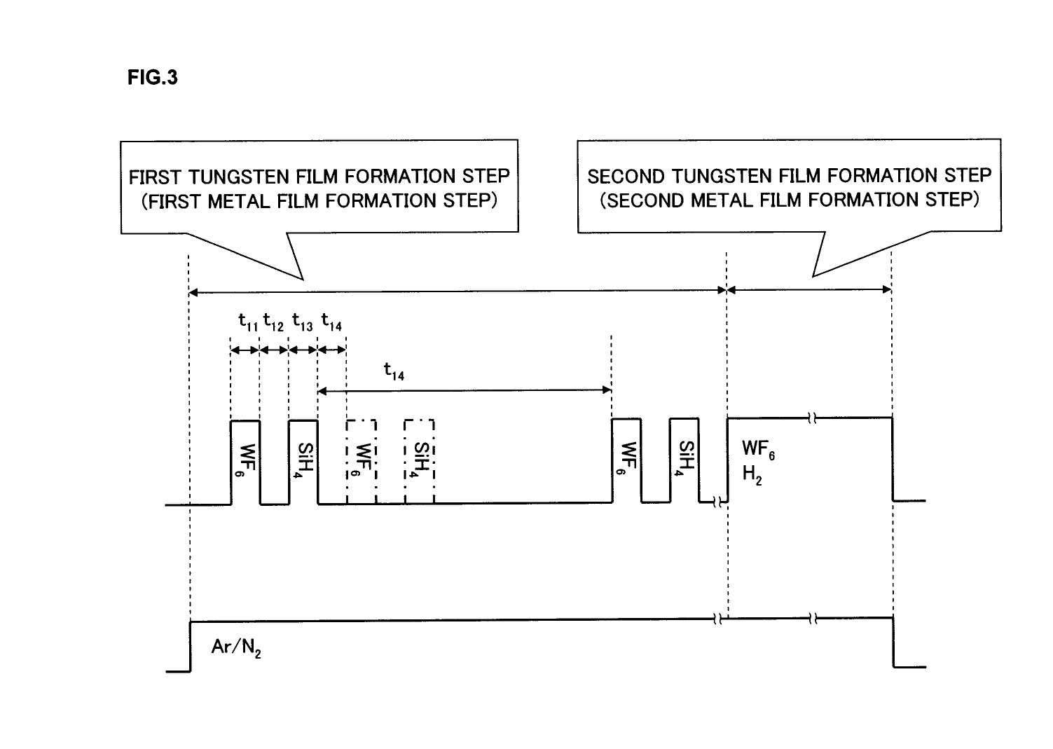

The following is an explanation of a specific example of a gas supply mode that may be adopted when supplying various gases during the individual film formation steps, given in reference to drawings. FIG. 3 presents a specific example of a gas supply mode that may be adopted when supplying various gases, whereas FIGS. 4A through 4D schematically illustrate the process through which a tungsten film is formed at the surface of the wafer M. In the gas supply mode shown in FIG. 3, the processing container 114 is continuously evacuated and also N₂ gas and/or Ar gas to be used as a carrier gas or a purge gas is supplied at a constant flow rate (or by adjusting the flow rate as needed) through the sequence of film formation steps. In addition, N₂ gas is supplied as necessary to be used as a purge gas for purging the residual film formation gas remaining in the processing container 114. The processing temperature for the individual film formation steps is set within a range of 300˜400° C., e.g., 350° C. This processing temperature setting may remain unchanged until the second tungsten film formation step ends.

### (Specific Example of the First Metal Film Formation Step)

First, the first tungsten film formation step is executed on the wafer M such as that shown in FIG. 4 A. In the first tungsten film formation step, a step of supplying the metal base material gas and a step of supplying a hydrogen compound gas or alternately executed multiple times with a purge step executed in between by supplying an inert gas so as to form a first tungsten film (first metal film) 220 with an amorphous content to be used as a nucleation layer (see FIG. 4B).

More specifically, the metal base material gas such as WF₆ gas and the hydrogen compound gas such as SiH₄ gas are alternately supplied over brief supply periods multiple times with a purge step for eliminating the gas having been supplied in the immediately preceding step from the container executed between the two gas supply steps. In the purge step, a purge gas constituted of, for instance, an inert gas such as N₂ gas should be supplied so as to promote the process of residual gas elimination.

In the first tungsten film formation step, the WF₆ gas molecular layer, which settles onto the wafer surface during the WF₆ gas supply step is reduced via SiH₄ gas supplied in the following SiH₄ gas supply step so as to allow a tungsten film to grow over several atom layers through each set of alternate gas supply steps. By repeating this process a given number of times, the first tungsten film 220 with a desired film thickness is formed (see FIG. 4B). Namely, the processing is executed over several cycles˜several tens of cycles as required, with a single cycle encompassing a period elapsing from a given WF₆ gas supply step to the following WF₆ gas supply step. It is desirable to set a layer of one molecule of WF₆ through a given cycle and form a single atom layer of W through the subsequent reaction with the reducing gas. By repeating this process, the first tungsten film can be formed as a completely amorphous film by effectively inhibiting crystal growth. It is to be noted that the inert gas may contain both N₂ gas and Ar gas or only either N₂ gas or Ar gas may be supplied to suit specific application requirements.

In addition, by adjusting the length of time over which the purge step is executed following the hydrogen compound gas (e.g., SiH₄ gas) supply step, the ratio of the amorphous content in the first tungsten film can be altered. For instance, by allowing the purge step to be executed over a greater length of time following the SiH₄ gas supply step, any excess gas at the wafer surface can be directly removed, the residual gas remaining in the processing container 114 can be completely removed and thus, re-adhesion of the gas onto the wafer surface can be reliably prevented. In other words, before setting the next WF₆ gas molecule layer, any excess SiH₄ gas that has not been used in the reaction can be removed from the wafer surface. This means that any residual SiH₄ gas molecules will react to the WF₆ gas as the WF₆ gas is next supplied to the wafer to presumably result in formation of a crystal nucleus similar to the nucleation layer in the related art.

Thus, in order to make the first tungsten film completely amorphous by inhibiting formation of such a crystal nucleus, it must be ensured that no SiH₄ gas molecules remain at the wafer surface when the WF₆ gas is supplied. The length over which the purge step is executed following the SiH₄ gas supply thus becomes a crucial factor.

While it is more desirable to set a considerable length of time for the execution time length t₁₄ over which the purge step is executed after the SiH₄ gas supply, the throughput becomes lower and the like if the purge step is executed over an excessively great length of time. Accordingly, it should be set to a length 6˜40 times the gas supply time lengths t₁₁ and t₁₂. For instance, t₁₄ should be set to approximately 10 sec ˜60 sec in correspondence to t₁₁˜t₁₃ set to approximately 1.5 sec. It is to be noted that the film forming rate per cycle, which is affected by the processing conditions, may be, for instance, 0.7˜1.2 nm under these circumstances, and the film thickness of the first tungsten film is normally set to 6˜7 nm.

By adjusting the length of the purge step executed after the SiH₄ gas supply as described above, the first tungsten film can be formed so as to be at least partially amorphous (the first tungsten film may be formed to become fully amorphous).

### (Specific Example of the Second Metal Film Formation Step)

The second tungsten film formation step is executed next. In the second tungsten film formation step, a second tungsten film (second metal film) 240 to constitute the main film layer is formed on top of the first tungsten film through a standard CVD method by simultaneously supplying the metal base material gas and a reducing gas (see FIG. 4C). It is to be noted that while the film thickness of the second tungsten film is set in correspondence to the diameter of the contact holes or the via holes, it is usually set within a range of 20˜40 nm.

More specifically, the metal base material gas such as WF₆ gas and the reducing gas such as H₂ gas are simultaneously supplied and the second tungsten film 240 is deposited at a high film formation rate through the CVD method, thereby completely filling an contact hole 210 (see FIG. 4C), as illustrated in FIG. 3.

The second tungsten film thus formed assumes a crystalline structure with a more dominant (110) plane orientation if the amorphous ratio in the first tungsten film is higher. In addition, as long as the first tungsten film is formed simply by ensuring that it achieves a high amorphous ratio, the second tungsten film with a dominant (110) plane orientation can be formed through any film forming method (e.g., a film forming method in the related art).

It is to be noted that once the second tungsten film formation step described above is completed, the wafer M is lowered from the film forming apparatus 100 to undergo etch-back processing or CMP (chemical-mechanical polishing) processing. As a result, a contact plug 250 is formed as shown in FIG. 4D with any excess tungsten film or barrier layer removed by planarizing the surface. Subsequently, specific processing is executed and semiconductor devices are manufactured.

It is to be noted that while the hydrogen compound gas constituted of SiH⁴ gas is used in the specific example of the gas supply mode shown in FIG. 3, the present invention is not limited to this example. For instance, a hydrogen compound gas constituted of B²H⁶ (diborane) gas or PH³ (phosphine) gas with a higher level of reducing strength than SiH⁴ gas, may be used in place of the SiH⁴ gas. The first metal film, e.g., the first tungsten film with amorphous content, can also be formed by using either of these alternative gases.

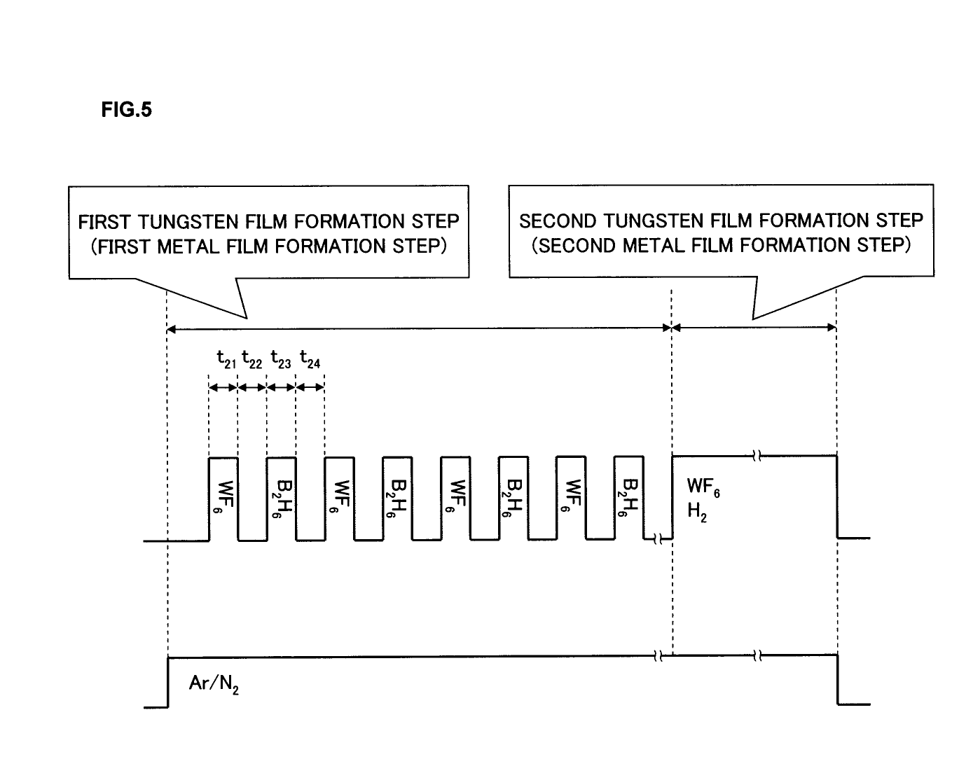

FIG. 5 presents a specific example of a gas supply mode that may be adopted to supply the various gases when B₂H₆ gas is used as the hydrogen compound gas. In the first tungsten film formation step the WF₆ gas and the B₂H₆ gas are alternately supplied over brief supply periods multiple times with a purge step for eliminating the gas having been supplied in the immediately preceding step from the container executed between the two gas supply steps, as shown in FIG. 5. In the purge step, a purge gas constituted of, for instance, an inert gas such as N₂ gas should be supplied so as to promote the process of residual gas elimination. It is to be noted that the inert gas may contain both N₂ gas and Ar gas or only either N₂ gas or Ar gas may be supplied to suit specific application requirements in this gas supply mode as well. It is desirable to supply N₂ gas or Ar gas to be used as a carrier gas while delivering the WF₆ gas, whereas it is advisable to supply Ar gas to be used as a carrier gas while delivering the B₂H₆ gas.

In the first tungsten film formation step, the WF₆ gas molecular layer, which settles onto the wafer surface during the WF₆ gas supply step is reduced via SiH₄ gas supplied in the following B₂H₆ gas supply step so as to allow a tungsten film to grow over several atom layers through each set of alternate gas supply steps. By repeating this process a given number of times, the first tungsten film with a desired film thickness is formed. Namely, the processing is executed over several cycles˜several tens of cycles as required, with a single cycle encompassing a period elapsing from a given WF₆ gas supply step to the following WF₆ gas supply step.

In addition, by adjusting the length of time over which the purge step is executed following the B₂H₆ gas supply step, the ratio of the amorphous content in the first tungsten film can be altered, as when SiH₄ gas is used as the hydrogen compound gas. Furthermore, B₂H₆ gas, which has a higher level of reducing strength than SiH₄ gas, may be diluted with a diluting gas having a reducing property such as H₂ gas, so as to allow direct removal of any excess gas from the wafer surface and fully eliminate any residual gas remaining in the processing container 114 in the subsequent purge step executed over a smaller length of time. In other words, even if the purge step is executed over a smaller length of time following the B₂H₆ gas supply step, a first tungsten film with amorphous content can be formed.

Accordingly, the B₂H₆ gas, diluted to, for instance, 5% with a diluting gas having a reducing property (e.g., H₂ gas) is supplied in the embodiment. By supplying B₂H₆ gas in a diluted formed as described above, a first tungsten film with amorphous content can be formed even if the purge step is executed over a smaller length of time following the B₂H₆ gas supply step than the length of time over which the purge step is executed in conjunction with SiH₄ gas used as the reducing gas. For instance, the length of the execution time t₂₄ for the purge step executed after the B₂H₆ gas supply step may be set to 1.5 sec in correspondence to t₂₁˜t₂₃ set to approximately 1.5 sec and still a first tungsten film that is fully amorphous can be formed.

Furthermore, by diluting the B₂H₆ gas with H₂ gas, the unstable B₂H₆ gas is still prevented from becoming decaborane through polymerization. Generated decaborane, collecting in the supply line path, may disable stable gas supply or may lead to the formation of particles. For this reason, it is desirable to dilute the B₂H₆ gas with H₂ gas, which is a polymerization inhibitor, and fill a pressure tank with the diluted B₂H₆ gas prior to the gas supply.

By using the B₂H₆ gas diluted with a diluting gas (e.g., H₂ gas) with a reducing property as described above, a first tungsten film with an amorphous content (or a fully amorphous first tungsten film) can be formed. This, in turn, makes it possible to form a second tungsten film assuming a crystalline structure with a dominant (110) plane orientation in the subsequent second tungsten film formation step. In addition, the amorphous ratio in the first tungsten film can be adjusted in correspondence to the extent to which the B₂H₆ gas is diluted. It is to be noted that since the second tungsten film formation step is executed as shown in FIG. 3, it is not explained in detail here.

As an alternative to the B₂H₆ gas, another hydrogen compound gas with a high level of reducing strength such as PH₃ gas may be used. In this case, too, H₂ gas may be used as a diluting gas to achieve, for instance, 5% PH₃ gas content. The use of PH₃ gas will achieve advantages similar to those of the B₂H₆ gas, e.g., a first tungsten film with an amorphous content can be formed even if the purge step is executed over a smaller length of time following the PH₃ gas supply step compared to the length of time over which the purge step is executed following the SiH₄ gas supply step.

### (Examination of the Crystalline Characteristics of the First Tungsten Film)

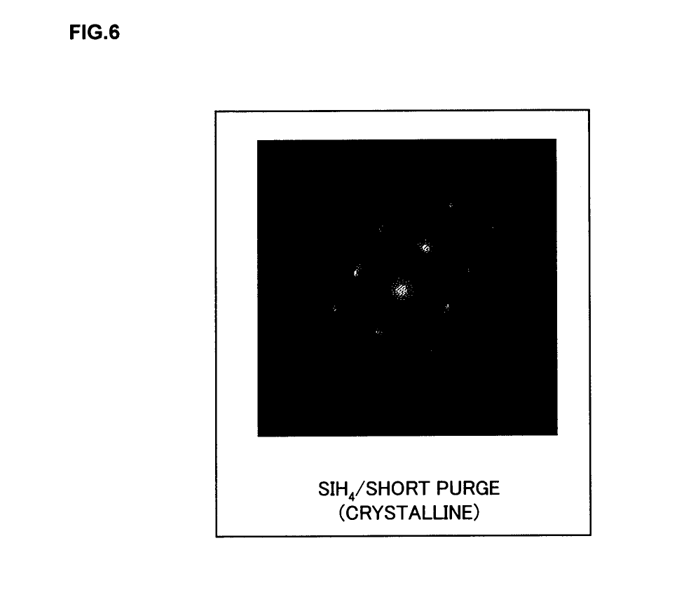

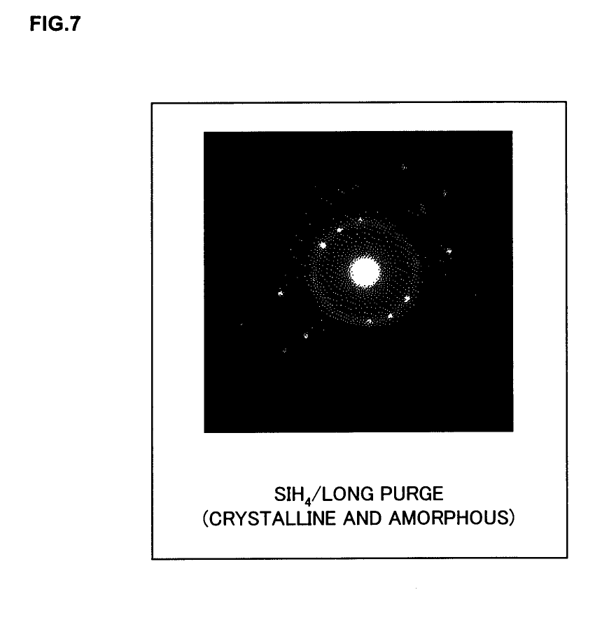

Next, the results obtained by examining the crystalline characteristics of the tungsten films actually formed on the film forming apparatus 100 are described. FIGS. 6 through 8 each present an electron beam diffraction image of a first tungsten film observed through an electron beam diffraction method. FIGS. 6 and 7 show first tungsten films formed by using the hydrogen compound gas constituted of SiH₄ gas in the gas supply mode shown in FIG. 3 with t₁₁ through t₁₃ set to 1.5 sec. The first tungsten film shown in FIG. 6 was formed by executing the purge step over a short execution time t₁₄ of approximately 1.5 sec, i.e., a first tungsten film formed through a “SiH₄/short purge” combination, whereas the first tungsten film shown in FIG. 7 was formed by executing the purge step over a long execution time t₁₄ of 60 sec, i.e., a first tungsten film formed through a “SiH₄/long purge” combination.

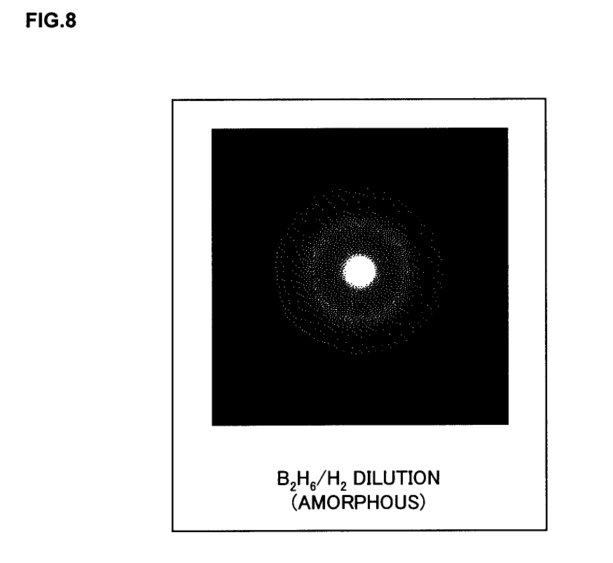

In addition, FIG. 8 shows a first tungsten film formed by diluting the hydrogen compound gas constituted of B₂H₆ gas with a diluting gas constituted of H₂ gas to 5% content in the gas supply mode shown in FIG. 5 with t₂₄ set as short as 1.5 in correspondence to t₂₁ through t₂₃ set to 1.5 sec, i.e., a first tungsten film formed under “B₂H₆/H₂ dilution” conditions.

Among these test results, the electron beam diffraction image in FIG. 6 contains diffraction spots with clear periodicity in the atomic arrangement, reflecting the crystalline structure of the tungsten. This indicates that when the purge step is executed over a small length of time following the SiH₄ gas supply step, in i.e., the “SiH₄/short purge” combination, the resulting tungsten film is crystalline. In addition, no halo pattern with a blurred outline reflecting an amorphous structure is observed in the electron beam diffraction image in FIG. 6, which indicates that the first tungsten film formed through the “SiH₄/short purge” combination assumes a fully crystalline structure with no amorphous content.

In contrast, the electron diffraction images in FIGS. 7 and 8 each contain a halo pattern reflecting the amorphous structure in the tungsten indicating that the first tungsten film formed by executing the purge step over a significant length of time (the “SiH₄/long purge” combination) following the SiH₄ gas supply step or using B₂H₆ gas diluted with H₂ gas (the “B₂H₆/H₂ dilution”) conditions assumes amorphous substance. Furthermore, the electron beam diffraction image presented in FIG. 7 also includes some diffraction spots in addition to the halo pattern, which indicates that the first tungsten film formed through the “SiH₄/long purge” combination contains both a crystalline substance and amorphous substance. The electron beam diffraction image in FIG. 8, on the other hand, contains no diffraction spots, indicating that the first tungsten film formed under the “B₂H₆/H₂ dilution” conditions assumes fully amorphous substance.

### (Examination of the Crystalline Structures of the Overall Tungsten Films)

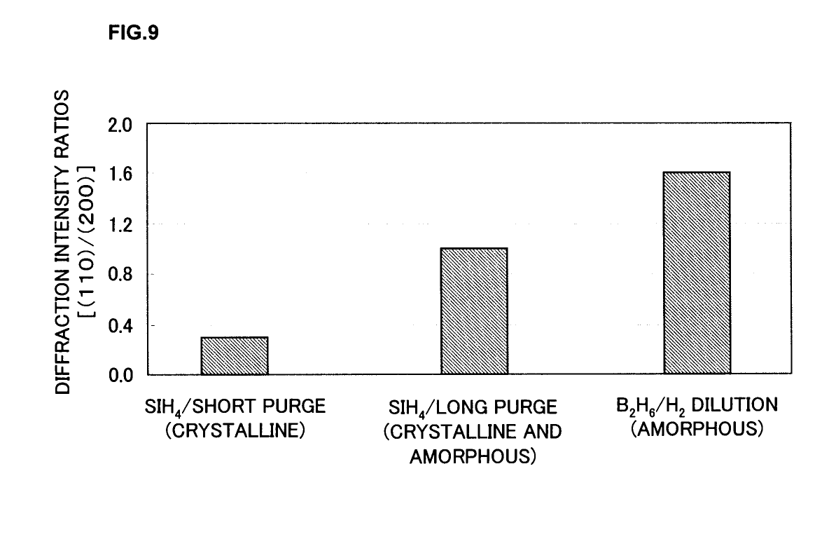

FIG. 9 presents the results obtained by examining the crystal structures of various tungsten films each formed by depositing a second tungsten film over one of the first tungsten films (see FIGS. 6 through 8) described above. FIG. 9 is a bar graph of the intensity ratio ((110)/(200)) of the diffraction peak intensities of the (110) plane orientation and the (200) plane orientation in body-centered cubic crystal structures observed through x-ray diffraction analysis of each tungsten film constituted with the first tungsten film and the second tungsten film. In the bar graph presented in FIG. 9, a greater intensity ratio ((110)/(200)) indicates a more dominant (110) plane orientation and a smaller intensity ratio ((110)/(200)) indicates a more dominant (200) plane orientation.

The bar graph presented in FIG. 9 indicates that the intensity ratio ((110)/(200)) of the tungsten film with the first tungsten film thereof assuming both crystalline substance and amorphous substance (see FIG. 7) formed through the “SiH₄/long purge” combination is higher than the intensity ratio of the tungsten film with the crystalline first tungsten film (see FIG. 6), formed through the “SiH₄/short purge” combination and the intensity ratio ((110)/(200)) of the tungsten film with the first tungsten film (see FIG. 8), formed under the “B₂H₆/H₂ dilution” conditions is higher than that of the tungsten film with the amorphous first tungsten film thereof assuming both crystalline substance and amorphous substance (see FIG. 7). In other words, as the amorphous content in the first tungsten film increases, a more dominant (110) plane orientation is achieved in the overall tungsten film, as shown in FIG. 9.

### (Examination of the Specific Resistances of the Overall Tungsten Films)

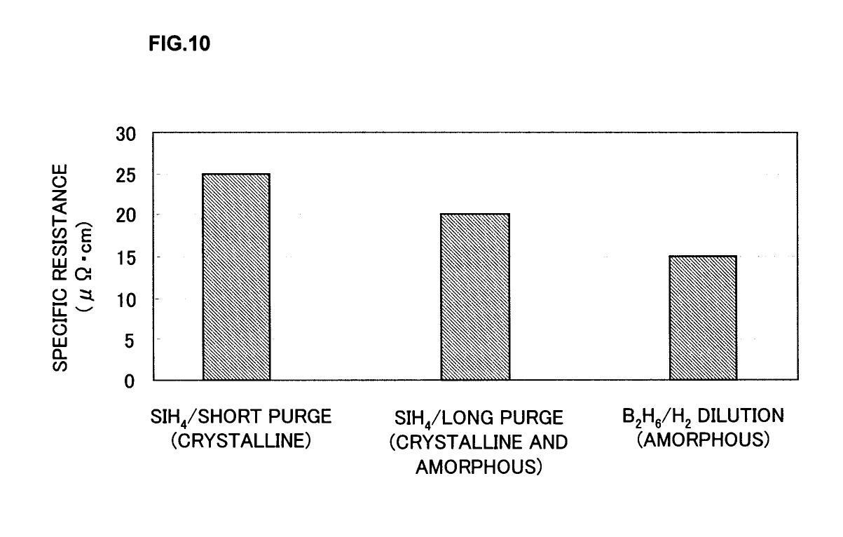

FIG. 10 presents the results obtained by examining the specific resistances of the individual tungsten films each formed by depositing the second tungsten film atop one of the various first tungsten films (see FIGS. 6 through 8) described above. FIG. 10 is a bar graph of the specific resistances of the overall tungsten films each constituted with the first tungsten film and the second tungsten film. It is to be noted that the first tungsten film was formed to a film thickness of 6 nm and that the second tungsten film was formed to a film thickness of 20 nm.

The bar graph in FIG. 10 indicates that the specific resistance becomes lower in the order of the tungsten film with the first tungsten film thereof assuming crystalline substance (see FIG. 6) formed through the “SiH₄/short purge” combination, the tungsten film with the first tungsten film thereof assuming both crystalline substance and amorphous substance (see FIG. 7) formed through the “SiH₄/long purge” combination and the tungsten film with the first tungsten film thereof assuming the amorphous substance (see FIG. 8) formed under the “B₂H₆/H₂ dilution” conditions. In other words, as the amorphous ratio in the first tungsten film becomes higher, the specific resistance of the overall tungsten film becomes lower, as shown in FIG. 10.

The specific resistance of the tungsten film with the first tungsten film thereof having amorphous content (e.g., the first tungsten film formed through the “SiH₄/long purge” combination) is reduced by approximately 20% over the specific resistance of the tungsten film with the first crystalline tungsten film of the related art (e.g., formed through the “SiH₄/short purge” combination), and the specific resistance of the tungsten film with the amorphous first tungsten film (e.g., formed under the “B₂H₆/H₂ dilution” conditions) is further reduced by approximately 40%. This means that a tungsten film with a much lower specific resistance over the related art can be formed through the embodiment.

As the test results presented in FIGS. 6 through 10 demonstrate, a more dominant (110) plane orientation is achieved as shown in FIG. 9 and a lower specific resistance is achieved, as shown in FIG. 10, in the tungsten film formed by depositing the second tungsten film on a first tungsten film with a higher amorphous content.

As explained above, the embodiment adopts the principle whereby a second metal film formed over a first metal film with amorphous content tends to readily assume an orientation (e.g., the (110) plane orientation in a body-centered cubic structure) with the highest atomic density and a stable atomic arrangement so as to form a metal film with a lower resistance. For instance, by forming a first tungsten film with amorphous content, the crystalline structure of a second tungsten film formed on top of the first tungsten film can be adjusted to assure a lower resistance (e.g., a crystalline structure with a dominant (110) plane orientation in a body-centered cubic structure), and ultimately, the resistance of the overall metal film is further lowered.

It is to be noted that while an explanation is given above on examples in which the first metal film is formed so as to assume amorphous substance (or a first metal film that is fully amorphous) by adjusting the length of execution time of the purge step executed following the step of supplying the hydrogen compound gas such as SiH₄ gas during the first tungsten film formation step, as shown in FIG. 3, or by diluting the hydrogen compound gas constituted with B₂H₆ gas or the like with H₂ gas as shown in FIG. 5, the present invention is not limited to these examples. The amorphous content in the first metal film may be otherwise adjusted by altering the inert gas supply mode or altering the pressure of the inert gas.

For instance, while the purge step is executed both after the metal base material gas supply step and the hydrogen compound gas supply step, the amorphous content in the first metal film may be adjusted by executing a step of stopping the inert gas supply at least during the purge step following the hydrogen compound gas supply step.

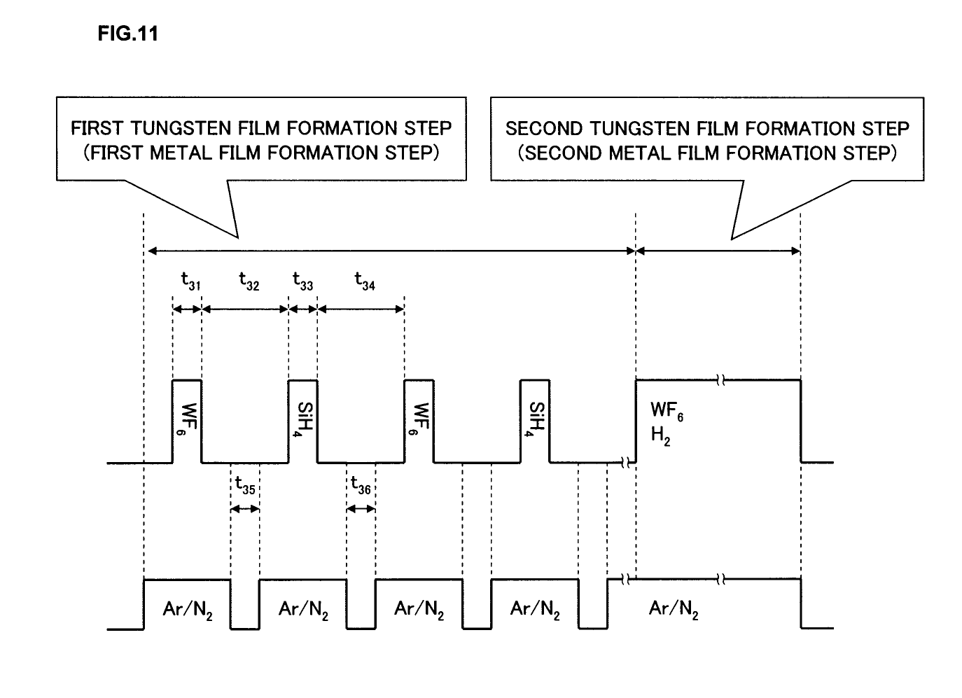

More specifically, a step of stopping the inert gas (Ar gas, N₂ gas) supply may be executed during each of the purge steps following the step of supplying the metal base material gas constituted of WF₆ gas and following the step of supplying the hydrogen compound gas constituted of SiH₄ gas, as in the gas supply mode shown in FIG. 11.

In this gas supply mode, the inert gas (Ar gas, N₂ gas) supply is completely stopped during substantially middle phases t₃₅ and t₃₆ in the purge steps t₃₂ and t₃₄. During these phases, the evacuation of the processing chamber alone is continuously executed, thereby rapidly lowering the internal pressure in the processing container 114. This rapid change in the internal pressure helps eliminate the residual gas on the wafer surface and inside the processing container 114 even more effectively.

As described above, by executing a step (t₃₆) of stopping the inert gas (Ar gas, N₂ gas) supply during the purge step (t₃₄) following the step of supplying the hydrogen compound gas constituted of SiH₄ gas, the residual gas on the wafer surface and inside the processing container 114 can be eliminated more effectively, which, in turn, ensures that a first tungsten film with an amorphous content can be formed with a high level of reliability even if the purge step is executed over a short period of time following the SiH₄ gas supply step.

In addition, by executing a step (e.g., t₃₅) of stopping the inert gas (Ar gas, N₂ gas) supply step during the purge step (t₃₂) following the step of supplying the metal base material gas constituted with WF₆ gas, the fluorine concentration in the first tungsten film can be reduced. This means that the fluorine concentration over the boundary of the barrier layer and thus tungsten film formed on top of the barrier layer can be reduced so as to inhibit formation of volcanoes and the like by minimizing diffusion of fluorine onto the barrier layer or the occurrence of a breakthrough eruption.

It is to be noted that while an explanation is given above in reference to the gas supply mode illustrated in FIG. 11 on an example in which the step of stopping the inert gas (Ar gas, N₂ gas) supply is executed during both purge steps following the WF₆ gas supply step and the SiH₄ gas supply step, the present invention is not limited to this example and a first tungsten film with amorphous content can be formed by, for instance, executing the step of stopping the inert gas (Ar gas, N₂ gas) supply only during the purge step following the SiH₄ gas supply step.

In addition, the inert gas (Ar gas, N₂ gas) supply may be stopped throughout the purge step executed after the SiH₄ gas supply step or the inert gas (Ar gas, N₂ gas) supply may also be stopped while the SiH₄ gas supply is in progress. Since the internal pressure in the processing container 114 is set to a low level through these measures, the residual gas remaining at the wafer surface and in the processing container 114 can be effectively eliminated, allowing a first tungsten film with amorphous content to be formed even when the purge step is executed over only a short period of time following the step of supplying the hydrogen compound gas constituted of, for instance, SiH₄ gas.

It is to be noted that the present invention described in detail above in reference the embodiment may be adopted in a system constituted with a plurality of devices or in an apparatus constituted with a single device. It will be obvious that the present invention may be carried out by providing a medium such as a storage medium having stored therein a software program for fulfilling the functions of the embodiment to the system or the apparatus and thus enabling a computer (a CPU or an MPU) of the system or the apparatus to read out and execute the program stored in the medium such as a storage medium.

In such a case, the program itself read out from the medium such as a storage medium embodies the functions of the embodiment described above and the medium such as a storage medium having the program stored therein embodies the present invention. The medium such as a storage medium through which the program is provided may be, for instance, a floppy (registered trademark) disk, a hard disk, an optical disk, a magneto-optical disk, a CD-ROM, a CD-R, a CD-RW, a DVD-ROM, a DVD-RAM, a DVD-RW, a DVD+RW, magnetic tape, a nonvolatile memory card, or a ROM. Alternatively, such a program may be obtained through a download via a network.

It is to be noted that the scope of the present invention includes an application in which an OS or the like operating on the computer executes the actual processing in part or in whole in response to the instructions in the program read out by the computer and the functions of the embodiment are achieved through the processing thus executed, as well as an application in which the functions of the embodiment are achieved as the computer executes the program it has read out.

The scope of the present invention further includes an application in which the program read out from the medium such as a storage medium is first written into a memory in a function expansion board loaded in the computer or a function expansion unit connected to the computer, a CPU or the like in the function expansion board or the function expansion unit executes the actual processing in part or in whole in response to the instructions in the program and the functions of the embodiment described above are achieved through the processing.

While the invention has been particularly shown and described with respect to a preferred embodiment thereof by referring to the attached drawings, the present invention is not limited to this example and it will be understood by those skilled in the art that various changes in form and detail may be made therein without departing from the spirit, scope and teaching of the invention.

For instance, while an explanation is given above in reference to the embodiment on an example in which the tungsten film is formed by using the metal base material gas constituted of WF₆ gas, the present invention is not limited to this example and instead, a Ta film, a TaN film or the like may be formed by using a metal base material gas constituted with a metal halogen compound, e.g., a TaCl-containing metal halogen compound. In addition, the metal base material gas used when forming the first metal film may be an organic tungsten compound and WF₆ gas may also be used as the metal base material gas for the second metal film.

### INDUSTRIAL APPLICABILITY

The present invention may be adopted in a metal film forming method for forming a metal film at the surface of a processing target piece and a recording medium having a program recorded therein.

1. A metal film forming method comprising:
a first metal film formation step in which a first metal film with amorphous content by alternately supplying multiple times a metal base material gas and a hydrogen compound gas; and
a second metal film formation step in which a second metal film is formed on top of said first metal film by simultaneously supplying said metal base material gas and a reducing gas.

2. A metal film forming method according to claim 1, wherein:
at least said second metal film assumes a body-centered cubic crystal structure.

3. A metal film forming method according to claim 1, wherein:
said first metal film is formed in said first metal film formation step by alternately executing multiple times a metal base material gas supply step in which the metal base material gas is supplied and a hydrogen compound gas supply step in which the hydrogen compound gas is supplied with a purge step executed between the metal base material gas supply step and the hydrogen compound gas supply step by supplying an inert gas.

4. A metal film forming method according to claim 3, wherein:
the ratio of the amorphous content in said first metal film is altered by adjusting the length of time over which said purge step is executed after said hydrogen compound gas supply step.

5. A metal film forming method according to claim 3, wherein:
the inert gas supply is stopped so as to alter the ratio of the amorphous content in the first metal film.

6. A metal film forming method according to claim 1, wherein:
at least said purge step executed after said hydrogen compound gas supply step includes a step in which said metal base material gas is a halogen compound gas.

7. A metal film forming method according to claim 1, wherein:
said hydrogen compound gas is SiH₄ gas, B₂H₆ gas or a mixed gas containing both the SiH₄ gas and the B₂H₆ gas.

8. A metal film forming method according to claim 3, wherein:
the ratio of the amorphous content in said first metal film is adjusted by diluting said hydrogen compound gas with a diluting gas having a reducing property.

9. A metal film forming method according to claim 8, wherein:
said hydrogen compound gas is B₂H₆ gas or PH₃ gas.

10. A metal film forming method according to claim 9, wherein:
said hydrogen compound gas is diluted to 5% or lower with H₂ gas.

11. A computer-readable recording medium having recorded therein a program that enables a computer to execute:
a first metal film formation step in which a first metal film with amorphous content by alternately executing multiple times a metal base material gas supply step and a hydrogen compound gas supply step with a purge step executed between said metal base material gas supply step and said hydrogen compound gas supply step; and
a second metal film formation step in which a second metal film is formed on top of said first metal film by simultaneously supplying said metal base material from gas and a reducing gas.
